(19) United States
(12) Patent Application Publication
(10) Pub. No.: US 2026/0324320 A1
(43) Pub. Date: Oct. 15, 2026

(54) METHOD OF TREATING THIN FILMS AND METHOD OF MANUFACTURING MEMORY DEVICE

(71) Applicant: EGTM Co., Ltd., Suwon-si, Gyeonggi-do (KR)

(72) Inventors: Kyu Ho CHO, Suwon-si, Gyeonggi-do (KR); Ha Na KIM, Suwon-si, Gyeonggi-do (KR); Hyun Ju JUNG, Suwon-si, Gyeonggi-do (KR); MYEONG IL KIM, Suwon-si, Gyeonggi-do (KR); Ju Hwan JEONG, Suwon-si, Gyeonggi-do (KR); Hyeon Sik CHO, Suwon-si, Gyeonggi-do (KR); Jae Min KIM, Suwon-si, Gyeonggi-do (KR); Sun Young BAIK, Suwon-si, Gyeonggi-do (KR)

(73) Assignee: EGTM Co., Ltd., Suwon-si, Gyeonggi-do (KR)

(21) Appl. No.: 19/176,681

(22) Filed: Apr. 11, 2025

(30) Foreign Application Priority Data
Jul. 22, 2024 (KR) 10-2024-0096766

(51) Int. Cl. H10P 50/26; H10P 50/28; H10P 50/66; H10P 50/68

(52) U.S. Cl. CPC H10P 50/269; H10P 50/285; H10P 50/667; H10P 50/683

(57) ABSTRACT

Disclosed is a method of a method of treating thin films, the method comprising supplying a modifier to the inside of a chamber where a substrate is placed to adsorb the modifier onto a thin film formed on the substrate; purging the inside of the chamber; supplying an etching activator to the inside of the chamber to react with the adsorbed modifier and treat the thin film; and purging the inside of the chamber.

### TECHNICAL FIELD

The present invention relates to a method of treating thin films and a method of manufacturing a memory device including the same. More specifically, it relates to a method of treating thin films using a modifier and an etching activator to enhance etching characteristics, and a method of manufacturing a memory device including the same.

### BACKGROUND

Conventional top-down patterning mechanisms have typically involved depositing a desired material as a thin film and then fabricating it to a desired size and shape through isotropic wet etching, anisotropic dry etching, reactive ion etching (RIE), etc. However, due to the continuous demand for high performance and low power consumption, as pattern sizes become increasingly miniaturized and innovation is required beyond current 3D structures to multi-dimensional stacked structures, etching technologies with high precision at the atomic level are needed beyond existing wet/dry etching technologies.

Accordingly, atomic layer etching methods inspired by atomic layer deposition have been developed. Conventional atomic layer etching methods were performed through a modification step that modifies the surface layer using hydrogen fluoride (HF), which is easily modifiable due to its strong reactivity, and a removal step that removes the modified surface layer by reacting with it.

However, hydrogen fluoride used in conventional atomic layer etching methods has the advantage of strong reactivity but has the problem that it is difficult to control the etching rate according to the input amount or to etch only a very thin thickness due to the diffusion of very small fluorine atoms. In addition, if fluorine atoms penetrate into undesired areas, they can cause damage and degrade the characteristics of the device, and the high temperature in the process of removing the modified surface layer can also cause degradation of the characteristics of the underlying film.

Therefore, to implement ideal ALE (Atomic Layer Etch) corresponding to the opposite concept of ALD (Atomic Layer Deposition), there is a need to develop materials and processes that can maintain a constant etching thickness through termination of surface reactions and control the etching rate.

An object of the present invention is to provide a method of treating thin films that can uniformly remove thin films and a method of manufacturing a memory device including the same.

Another object of the present invention is to provide a method of treating thin films that can easily adjust the thickness of thin films through a low etching rate and a method of manufacturing a memory device including the same.

Yet another object of the present invention is to provide a method of treating thin films that can maintain thin film characteristics without leaving impurities and a method of manufacturing a memory device including the same.

Other objects of the present invention will become more apparent from the following detailed description.

### SUMMARY

Disclosed is a method of a method of treating thin films, the method comprising supplying a modifier to the inside of a chamber where a substrate is placed to adsorb the modifier onto a thin film formed on the substrate; purging the inside of the chamber; supplying an etching activator to the inside of the chamber to react with the adsorbed modifier and treat the thin film; and purging the inside of the chamber.

The modifier may be represented by the following Chemical Formula 1:

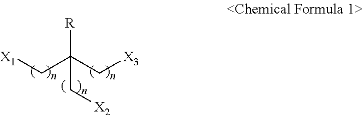

in <Chemical Formula 1>, n is each independently selected from integers of 0 to 5,
X₁ to X₃ are each independently selected from an alkoxy group having 1 to 5 carbon atoms, and a dialkylamino group having 1 to 5 carbon atoms, and
R is selected from hydrogen, a linear, branched, or cyclic alkyl groups having 1 to 5 carbon atoms, an alkoxy group having 1 to 5 carbon atoms, and a dialkylamino group having 1 to 5 carbon atoms.

The modifier may be represented by the following Chemical Formula 2:

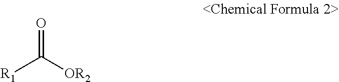

in <Chemical Formula 2>, R₁ is selected from a linear, branched, or cyclic alkyl groups having 1 to 5 carbon atoms, and a linear, branched, or cyclic chloroalkyl group having 1 to 5 carbon atoms,
R₂ is selected from hydrogen, a linear, branched, or cyclic alkyl groups having 1 to 5 carbon atoms.

The modifier may be represented by the following Chemical Formula 3:

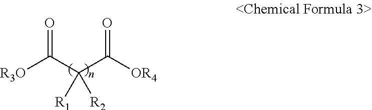

in <Chemical Formula 3>, n is selected from integers of 1 to 5,
R₁ and R₂ are selected from hydrogen, and chlorine element,
R₃ and R₄ are selected from hydrogen, a linear, branched, or cyclic alkyl groups having 1 to 5 carbon atoms.

The modifier may be represented by the following Chemical Formula 4:

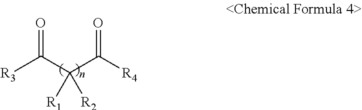

in <Chemical Formula 4>, n is selected from integers of 1 to 5,
R₁ and R₂ are selected from hydrogen, and chlorine element,
R₃ and R₄ are selected from hydrogen, a linear, branched, or cyclic alkyl groups having 1 to 5 carbon atoms.

The etching activator may be one of O₃, O₂, or H₂O.

The thin film may have Al, Ti, Hf, Nb, Ta, Mo, or W as a central element.

The thin film may be one of a metal film, metal oxide, metal nitride, or metal sulfide. In this case, the metal film may include Binary or Ternary compounds doped with one or more other elements for the purpose of improving characteristics.

The method may be carried out at 50 to 700° C.

Disclosed is a method of manufacturing a volatile memory device may include the aforementioned method of treating thin films.

Disclosed is a method of manufacturing a non-volatile memory device may include the aforementioned method of treating thin films.

### BRIEF DESCRIPTION OF THE DRAWINGS

FIG. 1 is a graph schematically showing a supply cycle according to an embodiment of the present invention.

FIG. 2 is a graph comparing the thin film thickness per cycle according to whether an etching activator is used in Example 1 of the present invention.

FIG. 3 is a graph showing the etching thickness per cycle according to whether an etching activator is used in Example 5 of the present invention.

FIG. 4 is a graph showing the etching thickness per cycle according to whether an etching activator is used in Example 6 of the present invention.

FIG. 5 is a graph showing the thickness of a MO thin film according to the supply time of the modifier in Example 7 of the present invention.

### DETAILED DESCRIPTION

Hereinafter, embodiments of the present invention will be described with reference to FIGS. 1 to 5. The embodiments of the present invention can be modified in various forms, and the scope of the present invention should not be interpreted as being limited to the embodiments described below.

FIG. 1 is a graph schematically showing a supply cycle according to an embodiment of the present invention. A substrate is loaded into a process chamber, and following ALD process conditions are adjusted. The process conditions may include a temperature of the substrate or process chamber, a pressure in the process chamber, gas flow rate, and the temperature is 50 to 700° C.

The substrate is exposed to the modifier supplied to the inside of the chamber, and the modifier is adsorbed to the thin film formed on the surface of the substrate. The thin film may have Al, Ti, Hf, Nb, Ta, Mo, or W as a central element, the thin film may be one of a metal film, metal oxide, metal nitride, or metal sulfide. In this case, the metal film may include Binary or Ternary compounds doped with one or more other elements for the purpose of improving characteristics. The modifier is supplied at 50 to 700° C.

Specifically, the modifier may be represented by the following Chemical Formula 1:

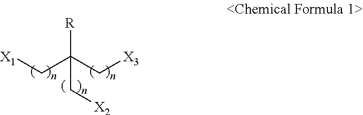

in <Chemical Formula 1>, n is each independently selected from integers of 0 to 5,
X₁ to X₃ are each independently selected from an alkoxy group having 1 to 5 carbon atoms, and a dialkylamino group having 1 to 5 carbon atoms, and
R is selected from hydrogen, a linear, branched, or cyclic alkyl groups having 1 to 5 carbon atoms, an alkoxy group having 1 to 5 carbon atoms, and a dialkylamino group having 1 to 5 carbon atoms.

Specifically, in the above <Chemical Formula 1>, when n=0, X₁ to X₃ are methoxy groups (—OCH₃), and R is a hydrogen atom, the modifier may be Trimethyl orthoformate.

Also, in the above <Chemical Formula 1>, when n=0, X₁ to X₃ are ethoxy groups (—OC₂H₅), and R is a hydrogen atom, the modifier may be Triethyl orthoformate.

Also, in the above <Chemical Formula 1>, when n=0, X₁ to X₂ are methoxy groups (—OCH₃), X₃ is dimethylamine groups (—N(CH₃)₂), and R is a hydrogen atom, the modifier may be Dimethylformamide Dimethyl Acetal.

Also, the modifier may be represented by the following Chemical Formula 2:

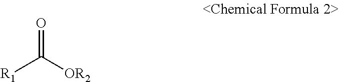

in <Chemical Formula 2>, R₁ is selected from a linear, branched, or cyclic alkyl groups having 1 to 5 carbon atoms, and a linear, branched, or cyclic chloroalkyl group having 1 to 5 carbon atoms,
R₂ is selected from hydrogen, a linear, branched, or cyclic alkyl groups having 1 to 5 carbon atoms.

Specifically, in the above <Chemical Formula 2>, when R₁ is a chloromethyl group (—CH₂Cl) and R₂ is a hydrogen atom, the modifier may be chloroacetic acid.

Also, in the above <Chemical Formula 2>, when R₁ is a dichloromethyl group (—CHCl₂) and R₂ is a methyl group, the modifier may be Methyl Dichloroacetate.

Also, the modifier may be represented by the following Chemical Formula 3:

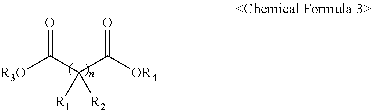

in <Chemical Formula 3>, n is selected from integers of 1 to 5,
R₁ and R₂ are selected from hydrogen, and chlorine element,
R₃ and R₄ are selected from hydrogen, a linear, branched, or cyclic alkyl groups having 1 to 5 carbon atoms.

Also, the modifier may be represented by the following Chemical Formula 4:

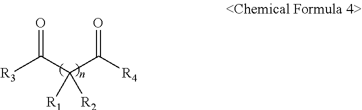

in <Chemical Formula 4>, n is selected from integers of 1 to 5,
R₁ and R₂ are selected from hydrogen, and chlorine element,
R₃ and R₄ are selected from hydrogen, a linear, branched, or cyclic alkyl groups having 1 to 5 carbon atoms.

Specifically, in the above <Chemical Formula 4>, when n=1, R₁ is hydrogen, R₂ is chlorine, and R₃ to R₄ are methyl groups, the modifier may be 3-Chloro-2,4-pentanedione.

However, the modifier is not limited to the above examples.

Thereafter, a purge gas (for example, an inert gas such as Ar) is supplied to the inside of the chamber to discharge the unadsorbed modifier or by-products.

Thereafter, the substrate is exposed to an etching activator supplied to the inside of the chamber, and the etching activator reacts with the modifier to etch the thin film. The etching activator is supplied at 50 to 700° C.

Specifically, the etching activator may be one of O₃, O₂, or H₂O. However, the etching activator is not limited to the above examples.

Thereafter, a purge gas (for example, an inert gas such as Ar) is supplied to the inside of the chamber to discharge the unreacted etching activator or by-products.

### Example 1: Trimethyl Orthoformate+O₃

Thin film of Nb₂O₅ was etched at 300° C., using Trimethyl Orthoformate (TMOF) as the modifier and O₃ as the etching activator.

The process of etching the thin film according to the supply cycle shown in FIG. 1 is as follows, and the following process is performed as one cycle.
1) a modifier is supplied to the inside of the chamber, and the modifier is adsorbed to the substrate
2) Ar gas is supplied to the inside of the chamber to discharge the unadsorbed modifier or byproducts
3) an etching activator is supplied to the inside of the chamber, and the etching activator reacts with the modifier to etch the thin film

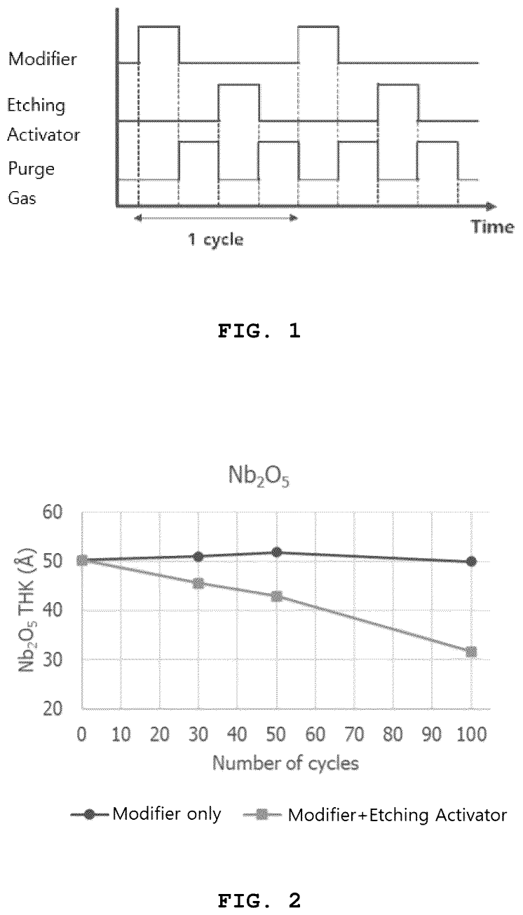

FIG. 2 is a graph comparing the thin film thickness per cycle according to whether an etching activator is used in Example 1 of the present invention. When only Trimethyl Orthoformate, a modifier, was used (TMOF only), almost no etching occurred in any thin film.

On the other hand, when an etching activator was used (TMOF+O₃), it was confirmed that the thickness of the thin film decreased linearly. It was confirmed that the thin film at the atomic layer level could be uniformly etched by the surface reaction of the two substances.

The modifier according to Example 1 of the present invention forms a modified monolayer through a substitution reaction with the metal element on the top surface, or exists on the surface through physical adsorption. Since the modifier has a very high reactivity of the central carbon due to the presence of oxygen atoms with high electronegativity, it can be easily dissociated when an etching activator is added to provide an alkoxy group on the surface, and it can be interpreted that it is removed by forming a volatile byproduct represented by M(OR)ₓ.

Table 1 below shows the etching rate according to the thin film confirmed through Example 1.

TABLE 1

| | | | Etching | Etching |
|---|---|---|---|---|
| Example | Sub. | Modifier | activator | rate(Å/cycle) |
| 1 | Nb₂O₃ | Trimethyl | O₃ | 0.18 |
| | | Orthoformate | | |

### Examples 2 to 4: Trimethyl Orthoformate+O₃

Thin films of TiO₂, Mo, MoN were etched at 380° C., using Trimethyl Orthoformate as the modifier and O₃ as the etching activator.

The process of etching the thin film according to the supply cycle shown in FIG. 1 was performed with the same cycle as Example 1.

Table 2 below shows the etching rate according to the thin films confirmed through Examples 2 to 4.

TABLE 1

| | | | Etching | Etching |
|---|---|---|---|---|
| Example | Sub. | Modifier | activator | rate(Å/cycle) |
| 2 | TiO₂ | Trimethyl | O₃ | 0.13 |
| | | Orthoformate | | |
| 3 | Mo | Trimethyl | O₃ | 3.51 |
| | | Orthoformate | | |
| 4 | MoN | Trimethyl | O₃ | 2.50 |
| | | Orthoformate | | |

Similar to Example 1, it was confirmed that the thin film at the atomic layer level could be uniformly etched by the surface reaction of the two substances.

### Example 5: Triethyl Orthoformate+O₃

Thin films of Nb₂O₅ and TiO₂ was etched at 340° C., using Triethyl Orthoformate (TEOF) as the modifier and O₃ as the etching activator.

The process of etching the thin film according to the supply cycle shown in FIG. 1 is as follows, and the following process is performed as one cycle.
1) a modifier is supplied to the inside of the chamber, and the modifier is adsorbed to the substrate
2) Ar gas is supplied to the inside of the chamber to discharge the unadsorbed modifier or byproducts
3) an etching activator is supplied to the inside of the chamber, and the etching activator reacts with the modifier to etch the thin film

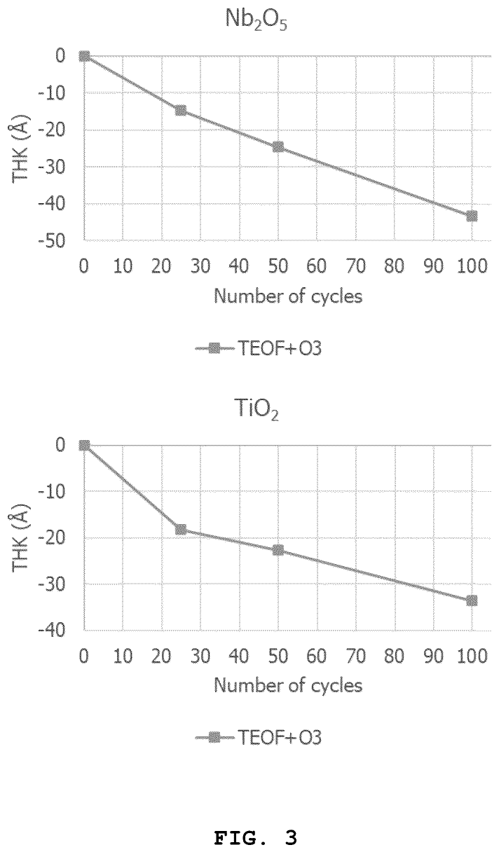

FIG. 3 is a graph showing the etching thickness per cycle according to whether an etching activator is used in Example 5 of the present invention. When Triethyl Orthoformate (TEOF), a modifier, and O₃, an etching activator, were used, it was confirmed that the thickness of the thin film decreased linearly. It was confirmed that the thin film at the atomic layer level could be uniformly etched by the surface reaction of the two substances.

### Example 6: Dimethylformamide Dimethyl Acetal+O₃

Thin films of Nb₂O₅ and TiO₂ was etched at 340° C., using Dimethylformamide Dimethyl Acetal (DFDA) as the modifier and O₃ as the etching activator.

The process of etching the thin film according to the supply cycle shown in FIG. 1 is as follows, and the following process is performed as one cycle.
1) a modifier is supplied to the inside of the chamber, and the modifier is adsorbed to the substrate
2) Ar gas is supplied to the inside of the chamber to discharge the unadsorbed modifier or byproducts
3) an etching activator is supplied to the inside of the chamber, and the etching activator reacts with the modifier to etch the thin film

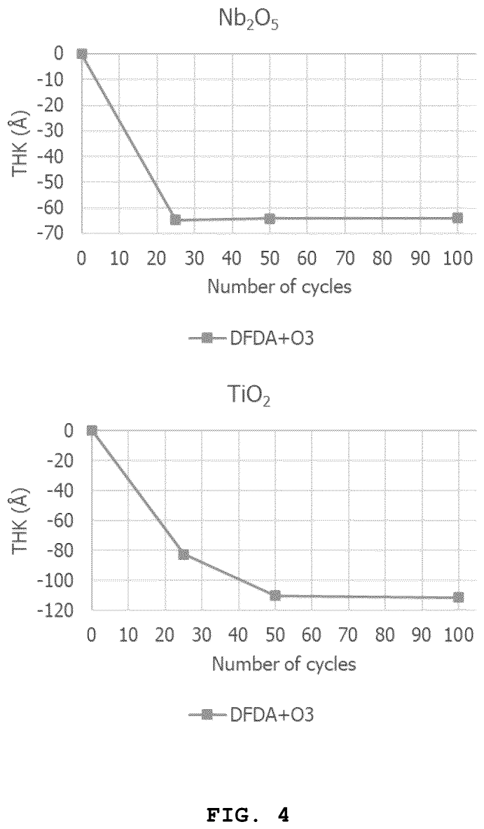

FIG. 4 is a graph showing the etching thickness per cycle according to whether an etching activator is used in Example 6 of the present invention. When Dimethylformamide Dimethyl Acetal, a modifier, and O₃, an etching activator, were used, it was confirmed that the thickness of the thin film decreased linearly and the etching rate was relatively high so that the thin film was completely etched after 50 cycles. It was confirmed that the thin film at the atomic layer level could be uniformly etched by the surface reaction of the two substances.

### Example 7: Dimethylformamide Dimethyl Acetal+O₃

Thin film of MO was etched at 150° C., using Dimethylformamide Dimethyl Acetal (DFDA) as the modifier and O₃ as the etching activator.

The process of etching the thin film according to the supply cycle shown in FIG. 1 is as follows, and the following process is performed as one cycle.
1) a modifier is supplied to the inside of the chamber, and the modifier is adsorbed to the substrate
2) Ar gas is supplied to the inside of the chamber to discharge the unadsorbed modifier or byproducts
3) an etching activator is supplied to the inside of the chamber, and the etching activator reacts with the modifier to etch the thin film

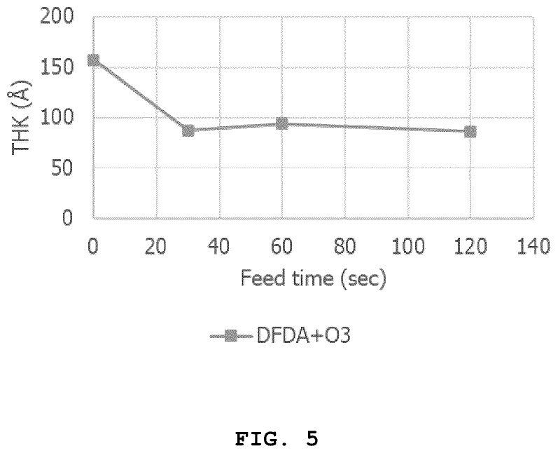

FIG. 5 is a graph showing the thickness of a MO thin film according to the supply time of the modifier in Example 7 of the present invention. When Dimethylformamide Dimethyl Acetal, a modifier, and O₃, an etching activator, were used, it was confirmed that etching did not occur continuously but rather reached saturation even when the supply time of the modifier was increased. It was confirmed that the thin film at the atomic layer level could be uniformly etched at an etching rate of 3.9 Å/cycle.

According to embodiments of the present invention, thin films can be uniformly removed.

Additionally, since the modifier is uniformly adsorbed onto the surface of the etching target material in atomic layers, the degree of etching can be accurately controlled compared to conventional etching methods.

The present invention has been explained in detail with reference to embodiments, but other embodiments may be included. Accordingly, the technical idea and scope described in the claims below are not limited to the embodiments.

1. A method of treating thin films, the method comprising:
supplying a modifier to the inside of a chamber where a substrate is placed to adsorb the modifier onto a thin film formed on the substrate;
purging the inside of the chamber;
supplying an etching activator to the inside of the chamber to react with the adsorbed modifier and treat the thin film; and
purging the inside of the chamber.

2. The method of claim 1, wherein the modifier is represented by the following Chemical Formula 1: 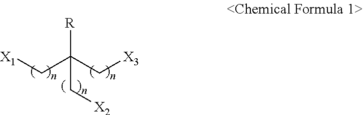
in <Chemical Formula 1>, n is each independently selected from integers of 0 to 5,
X₁ to X₃ are each independently selected from an alkoxy group having 1 to 5 carbon atoms, and a dialkylamino group having 1 to 5 carbon atoms, and
R is selected from hydrogen, a linear, branched, or cyclic alkyl groups having 1 to 5 carbon atoms, an alkoxy group having 1 to 5 carbon atoms, and a dialkylamino group having 1 to 5 carbon atoms.

3. The method of claim 1, wherein the modifier is represented by the following Chemical Formula 2: 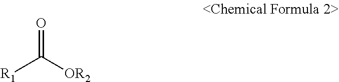
in <Chemical Formula 2>, R₁ is selected from a linear, branched, or cyclic alkyl groups having 1 to 5 carbon atoms, and a linear, branched, or cyclic chloroalkyl group having 1 to 5 carbon atoms,
R₂ is selected from hydrogen, a linear, branched, or cyclic alkyl groups having 1 to 5 carbon atoms.

4. The method of claim 1, wherein the modifier is represented by the following Chemical Formula 3: 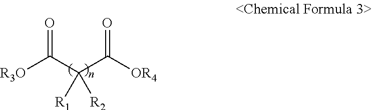
in <Chemical Formula 3>, n is selected from integers of 1 to 5,
R₁ and R₂ are selected from hydrogen, and chlorine element,
R₃ and R₄ are selected from hydrogen, a linear, branched, or cyclic alkyl groups having 1 to 5 carbon atoms.

5. The method of claim 1, wherein the modifier is represented by the following Chemical Formula 4: 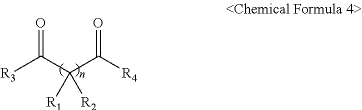
in <Chemical Formula 4>, n is selected from integers of 1 to 5,
R₁ and R₂ are selected from hydrogen, and chlorine element,
R₃ and R₄ are selected from hydrogen, a linear, branched, or cyclic alkyl groups having 1 to 5 carbon atoms.

6. The method of claim 1, wherein the etching activator is one of O₃, O₂, or H₂O.

7. The method of claim 1, wherein the thin film has Al, Ti, Hf, Nb, Ta, Mo, or W as a central element.

8. The method of claim 1, wherein the thin film has one of a metal film, metal oxide, metal nitride, or metal sulfide.

9. The method of claim 1, wherein the method is carried out at 50 to 700° C.

10. A method of manufacturing a volatile memory device, the method comprising the method of treating thin films according to claim 1.

11. A method of manufacturing a non-volatile memory device, the method comprising the method of treating thin films according to claim 1.

12. A method of manufacturing a volatile memory device, the method comprising the method of treating thin films according to claim 2.

13. A method of manufacturing a volatile memory device, the method comprising the method of treating thin films according to claim 3.

14. A method of manufacturing a volatile memory device, the method comprising the method of treating thin films according to claim 4.

15. A method of manufacturing a volatile memory device, the method comprising the method of treating thin films according to claim 5.

16. A method of manufacturing a volatile memory device, the method comprising the method of treating thin films according to claim 6.

17. A method of manufacturing a non-volatile memory device, the method comprising the method of treating thin films according to claim 2.

18. A method of manufacturing a non-volatile memory device, the method comprising the method of treating thin films according to claim 3.

19. A method of manufacturing a non-volatile memory device, the method comprising the method of treating thin films according to claim 4.

20. A method of manufacturing a non-volatile memory device, the method comprising the method of treating thin films according to claim 5.
